(19) United States
(12) Patent Application Publication
(10) Pub. No.: US 2012/0012908 A1
(43) Pub. Date: Jan. 19, 2012

(54) SEMICONDUCTOR DEVICE

(76) Inventor: Koji Matsunaga, Tokyo (JP)

(21) Appl. No.: 13/138,781

(22) PCT Filed: Mar. 26, 2010
(86) PCT No.: PCT/JP2010/055321

§ 371 Date: Sep. 28, 2011

(30) Foreign Application Priority Data
Mar. 30, 2010 (JP) 2009 083063

(51) Int. Cl. H01L 27/092

(52) U.S. Cl. 257/296; 257/E27.062

(57) ABSTRACT

The semiconductor device of the present invention includes a source electrode, a drain electrode, a gate electrode and a gate power feeding line. The gate electrode is disposed between said source electrode and said drain electrode. The gate power feeding line is connected to both ends of said gate electrode.

### TECHNICAL FIELD

The present invention relates to a multi-finger (comb-form configuration) transistor, and in particular, relates to a multi-finger transistor to be used in a microwave bandwidth.

### BACKGROUND ART

FIG. 1 is a schematic view for describing about a configuration of a multi-finger FET (Field Effect Transistor) of an art related to the present invention. This multi-finger FET includes a gate section, a source section and a drain section. Here, the gate section includes a gate electrode pad 1, a gate bus bar 4 and a plurality of gate fingers 5. The source section includes a source electrode pad 2, a plurality of source electrodes 6 and a plurality of via holes 3. The drain section includes a drain electrode pad 8 and a plurality of drain electrodes 7.

The plurality of source electrodes 6 and the plurality of drain electrodes 7 are alternatively disposed, one by one. Also, one gate finger 5 is disposed between a source electrode 6 and a drain electrode 7 which are next to each other.

In the gate section, the gate electrode pad 1 is connected to the plurality of gate fingers 5 via the gate bus bar 4.

In the source section, the source electrode pad 2 is connected to the plurality of via holes 3 via the air bridge.

The plurality of via holes 3 are grounded. The plurality of via holes 3 are connected to the plurality of source electrodes 6, respectively.

In the drain section, the drain electrode pad 8 is connected to the plurality of drain electrodes 7.

In the multi-finger FET which is configured as above, an associated capacity and a resistor in series per unit length of each gate finger 5 are symbolized by C and R, respectively. Also, a finger-length of the gate finger 5 is symbolized by Lw.

FIG. 2 is a schematic view for describing about a coordinate system which is set to the gate section in the multi-finger FET of an art related to the present invention. This gate section is identical to a part extracted from the gate section in FIG. 1. This gate section includes a gate electrode pad 9, a gate bus bar 10 and a plurality of gate fingers 11. That is, the gate electrode pad 9, the gate bus bar 10 and the plurality of gate fingers 11 in FIG. 2 correspond to the gate electrode pad 1, the gate bus bar 4 and the plurality of gate fingers 5 in FIG. 1, respectively.

In FIG. 2, a position of a root of the gate finger 11 which is connected to the gate bus bar 10 is set as an origin, and a length direction of the gate finger 11 is set as an x-axis. In such coordinate system, a coordinate of an end of the gate finger 11 is Lw.

In this coordinate system, a voltage equation of a distance x of any gate finger 11 from the gate bus bar 10, that is the coordinate x, can be shown, with distribution constants, as below.

∂V²(x)/∂x=CR∂V(x)/∂t

A current component I(x) and a voltage component V(x) can be obtained by using an input voltage V₀ inputted to the gate in a boundary condition of the gate finger 11. The boundary condition in FIG. 2 is as below.

V(0)=V₀

I(Lw)=0

In the multi-finger FET of the related art, by using a distribution constant expression, a current and a voltage on an arbitrary point of the gate finger are not uniform if an end of the finger is open. This means that device characteristics of the gate finger vary by position and that device characteristics of the multi-finger FET easily fluctuate.

In the configuration of the multi-finger FET of the related art, by using the distribution constant expression, the current and the voltage in the gate finger are not uniform. Therefore, a source inductance seen from the gate finger varies by from which position of the gate finger it is seen. As the result, a device gain characteristic is influenced; it is a subject existing in the multi-finger FET of the related art.

Also, a decrease of the FET gain is contributed by the source inductance. However, in the multi-finger FET of the related art, the via hole is connected to only one side of the source electrode. Thus, the source inductance seen from the gate finger varies in accordance with from which position of the gate finger from it is seen. In particular, an increase of the source inductance seen from an end of the gate finger causes a significant deterioration of the device gain characteristic. This is also a subject existing in the multi-finger FET of the related art.

Furthermore, if a starting point and an end point of the multi-finger are connected to one end of the gate power feeding line, the gate power feeding line becomes a closed circuit. In this case, if conditions are met, a loop oscillation occurs and the multi-finger FET may become unstable. This is also a subject existing in the multi-finger FET of the related art.

In relation with above, a description about a semiconductor device is disclosed in a first patent literature (Japanese Laid-Open Application 2000-138236). This semiconductor device is using a field effect transistor in which each of a plurality of source electrodes is disposed on a same axis and connected via a conductor; this field effect transistor has a gate electrode and a drain electrode, both of which are configured in a comb-form. This semiconductor device has via holes, each of which is configured to ground each ground electrode, respectively and correspondingly; each ground electrode is connected to a corresponding source electrode disposed on both ends of each of source electrodes. Each via hole has an elliptic hole shape.

### Citation List

### Patent Literature

PTL 1: Japanese Laid-Open Application 2000-138236

### SUMMARY OF INVENTION

A subject of the present invention is to provide a multi-finger FET in which a source inductance seen from each point of a gate finger is uniform and stable.

The semiconductor device of the present invention includes a source electrode, a drain electrode, a gate electrode and a gate power feeding line. Here, the gate electrode is disposed between the source electrode and the drain electrode. The gate power feeding line is connected to both ends of the gate electrode.

In the semiconductor device of the present invention, a source inductance seen from each point of the gate finger is uniform and stable. Therefore, a higher gain of a FET is realized in a bandwidth like microwave or millimeter-wave.

The subject, the effect and the characteristics of the above invention are more clarified by exemplary embodiments in cooperation with attached drawings.

### BRIEF DESCRIPTION OF DRAWINGS

FIG. 1 is a schematic view for describing about a configuration of a multi-finger FET of an art related to the present invention.

FIG. 2 is a schematic view for describing about a coordinate system which is set to the gate section in the multi-finger FET of an art related to the present invention.

FIG. 3 is a schematic view for describing about an overall configuration of a multi-finger FET of a first exemplary embodiment of the present invention.

FIG. 4 is a schematic view for describing about a coordinate system which is set to the gate section of the multi-finger FET of the first exemplary embodiment of the present invention.

FIG. 5 is a schematic view for describing about an overall configuration of a semiconductor device of a second exemplary embodiment of the present invention.

FIG. 6 is a graph showing a result of a gain characteristic of a high frequency FET obtained in a bandwidth of 38 GHz in accordance with a source inductance (parasitic inductance) value.

FIG. 7 is a schematic view for describing about an overall configuration of a semiconductor device of a third exemplary embodiment of the present invention.

FIG. 8A is a circuit diagram for describing about a closed circuit obtained by excluding a ladder circuit from the semiconductor device of the present exemplary embodiment.

FIG. 8B is a graph for describing about a result of calculating a phase difference of a closed circuit obtained by excluding a ladder circuit from the semiconductor device of the present exemplary embodiment.

FIG. 9A is a circuit diagram for describing about the semiconductor of the present exemplary embodiment, that is, a closed circuit in which a ladder circuit is provided.

FIG. 9B is a graph for describing about a result of calculating a phase difference of the semiconductor of the present exemplary embodiment, that is, a closed circuit in which a ladder circuit is provided.

FIG. 10 is a schematic view for describing about a configuration in an example of an MMIC (Monolithic Microwave Integrated Circuit) based on the multi-finger configuration of the semiconductor device of the present invention.

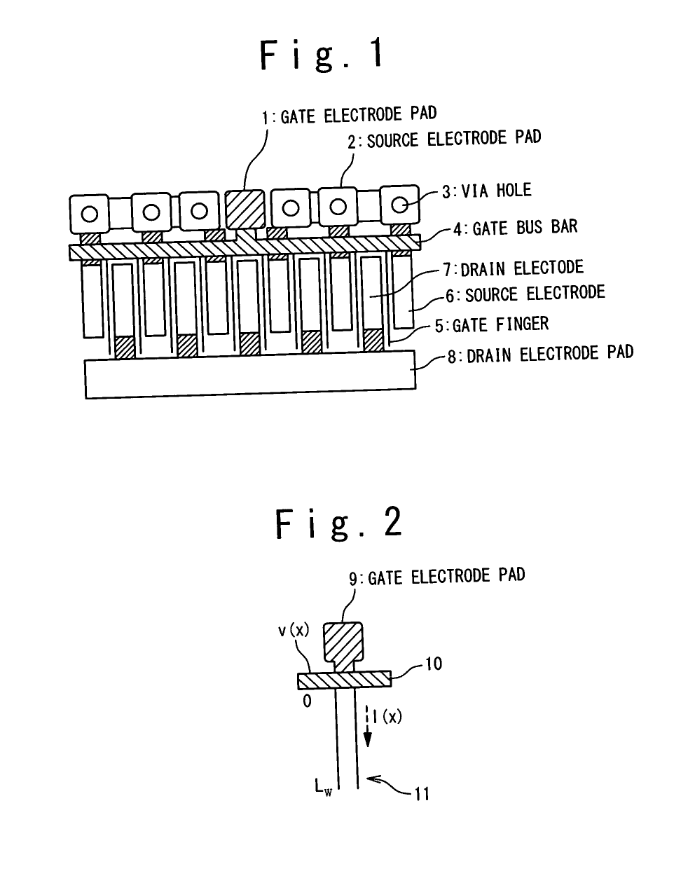

### DESCRIPTION OF EMBODIMENTS

Hereinafter, exemplary embodiments of a semiconductor device of the present invention will be described with reference to attached drawings.

### First Exemplary Embodiment

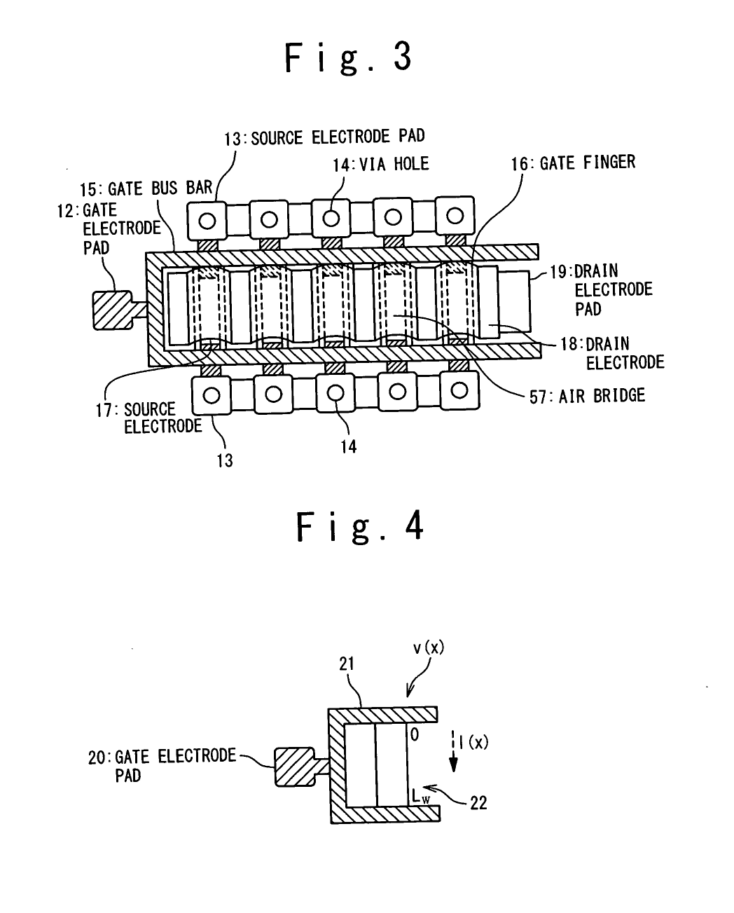

FIG. 3 is a schematic view for describing about an overall configuration of a semiconductor device of a first exemplary embodiment of the present invention. This semiconductor device is a multi-finger FET and includes a source section, agate section and a drain section. Here, the source section includes two source electrode pads 13, a plurality of via holes 14 and a plurality of source electrodes 17. The gate section includes a gate electrode pad 12, a gate bus bar 15 and a plurality of gate fingers 16. The gate bus bar 15 includes two end sections. The drain section includes a drain electrode pad 19, a plurality of air bridges 57 and a plurality of drain electrodes 18. Furthermore, numbers of the source electrodes 17, drain electrodes 18 and gate fingers 16, which are respectively 5, 6 and 10 in FIG. 3 as an example, are not to be used as limitation of the present invention.

Here, the gate fingers 16 work as gate electrodes. The gate bus bar 15 works as gate power feeding line. Via holes 14 are grounded and work as ground sections.

The plurality of source electrodes 17 and the plurality of drain electrodes 18 are alternatively disposed, one by one. Also, one gate finger 16 is disposed between a source electrode 17 and a drain electrode 18 which are next to each other.

In the source section, two source electrode pads 13 are connected to the plurality of via holes 14. Each of the plurality of via holes 14 is grounded. In each of the plurality of source electrodes, one end is connected to one of the source electrode pads 13 and another end is connected to the other one of the source electrode pads 13.

In the gate section, the gate electrode pad 12 is connected to a middle section of the gate bus bar 15. A part of the gate bus bar 15 from the position where the gate electrode pad 12 is connected to one end will be called one end section of the gate bus bar 15. Similarly, another part of the gate bus bar 15 from the position where the gate electrode pad 12 is connected to another end will be called other end section of the gate bus bar 15. Each of the two end sections of the gate bus bar 15 are disposed along an aligned set of the plurality of source electrode 17, the plurality of drain electrode 18 and the plurality of gate fingers 16. Both ends of the plurality of gate fingers 16 are connected to the one end section and the other end section of the gate bus bar 15. Therefore, the whole area of every gate fingers 16 has a same voltage.

In the drain section, drain electrode pad 19 is connected to a first drain electrode 18. The first drain electrode 18 is connected to a first air bridge 57. The first air bridge 57 is connected to a second drain electrode 18. Here, the first air bridge 57 crosses two gate fingers 16 and one source electrode 17 which are disposed between the first drain electrode 18 and the second drain electrode 18. Similarly, the plurality of drain electrodes 18 and the plurality of air bridges 57 are alternatively connected, one by one, and, each air bridge 57 crosses two gate fingers 16 and one source electrode 17 which are disposed between two drain electrodes 18 connected to both ends of the air bridge 57.

FIG. 4 is a schematic view for describing about a coordinate system which is set to the gate section of the multi-finger FET of the first exemplary embodiment of the present invention. This gate section is identical to a part extracted from the gate section in FIG. 3. This gate section includes a gate electrode pad 20, a gate bus bar 21 and a plurality of gate fingers 22. That is, the gate electrode pad 20, the gate bus bar 21 and the plurality of gate fingers 22 in FIG. 4 correspond to the gate electrode pad 12, the gate bus bar 15 and the plurality of gate fingers 16 in FIG. 3, respectively.

In FIG. 4, one end section of the gate finger 22, that is a position of one root connected to the gate bus bar 21, is set as an origin and a length direction of the gate finger is set as x axis. In such coordinate system, a coordinate of another end section of the gate finger 22 is Lw. Here, Lw is a length of the gate finger 22.

In this coordinate system, a voltage equation in a distance x from the one end section of any gate finger 22, that is a coordinate x, can be shown with distribution constants, as below.

∂V²(x)/∂x=CR∂V(x)/∂t

Here, C and R show a parasitic capacitance and serial resistance by a unit length of any gate finger 5, respectively.

Also, a boundary condition can be shown as below.

V(0)=V(Lw)=V₀

An input impedance of the gate finger 22 can be shown as below.

Zᵢₙ(x)=V(x)/I(x)

Its real resistance component, which is

Re[Zᵢₙ(x=0)]

shows a gate resistance. Therefore, the gate resistance can be obtained by above boundary condition.

By connecting both ends of the gate finger 22 to the gate bus bar 21, a voltage becomes uniform in a whole area of the gate finger 22; in such case, the gate resistance will be as below.

Re[Zᵢₙ(0)]=( 1/12)RLw

Incidentally, the gate resistance in a case where the one end section of the gate finger is connected to the gate bus bar 21 and the other end section is open, as same as the multi-finger FET presented as a related art, is as below.

Re[Zin(0)]=(⅓)RLw

This result shows that, in the case where both ends of the gate finger 22 are connected to the gate bus bar so that the voltage becomes uniform in a whole area of the gate finger, the gate resistance can be decreased to ¼ of the related art configuration.

Therefore, by decreasing the gate resistance, the multi-finger FET of the present invention can be obtain a higher gain.

Also, since both ends of the gate finger are connected to the gate bus bar in the multi-finger FET configuration of the present invention, the voltage is uniform in whole area of the gate finger and an influence of device characteristics variability is small.

### Second Exemplary Embodiment

FIG. 5 is a schematic view for describing about an overall configuration of a semiconductor device of a second exemplary embodiment of the present invention. This semiconductor device is a variation of the semiconductor device in the first exemplary embodiment in which the number of the source electrodes 28 is changed into one. As a result, the number of the drain electrode 29 is changed into two and the number of the gate finger 27 is changed into two, respectively. It is to say that, this exemplary embodiment is a minimal configuration of the multi-finger FET as the semiconductor device of the present invention.

This semiconductor device further includes two source electrode pads 25, two via holes 26, a gate electrode pad 23, a gate bus bar 24, a drain electrode pad 30 and an air bridge 58. The two source electrode pads 25, the two via holes 26, the gate electrode pad 23, the gate bus bar 24 and the drain electrode pad 30 of FIG. 5 correspond to the plurality of source electrode pads 13, the plurality of via holes 14, gate electrode pad 12, the gate bus bar 15 and the drain electrode pad 19 of FIG. 3, respectively.

As shown in FIG. 5, two via holes 26 which are connected to the source electrode 28 are disposed at both end of the source electrode 28. As a result, a decrease of a source inductance is attempted and, in same time, an influence of a source inductance seen from each point of the gate finger 27 can be reduced.

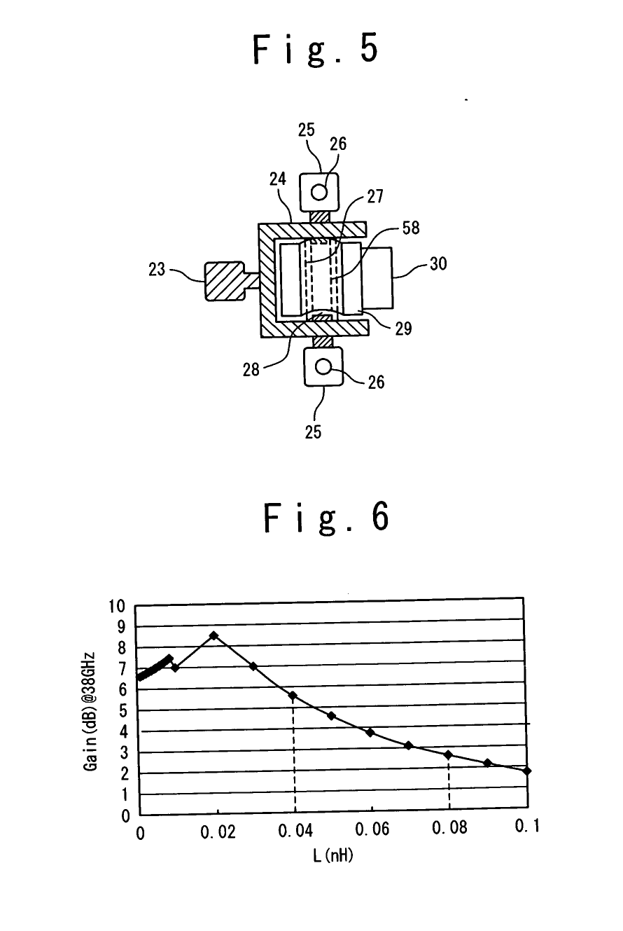

FIG. 6 is a graph showing a result of a gain characteristic of a high frequency FET obtained in a bandwidth of 38 GHz in accordance with a source inductance (parasitic inductance) value. In this graph, the horizontal axis shows a value L of source inductance and the vertical axis shows the gain characteristics, respectively.

A value of the source inductance of the semiconductor device of the related art was 0.08 nH. It can be understood from the graph of FIG. 6 that, if the value of the source inductance is halved into 0.04 nH the gain characteristic can be brought near about 6.8 dB which is the ideal value.

Thus, by connecting both ends of the gate finger 27 to the gate bus bar 24 and grounding the source electrode 28 via the via holes 26 which are disposed on both ends of the source electrode 28, the multi-finger FET of the present invention can obtain, in a high frequency, a higher gain characteristic than in the relate art.

### Third Exemplary Embodiment

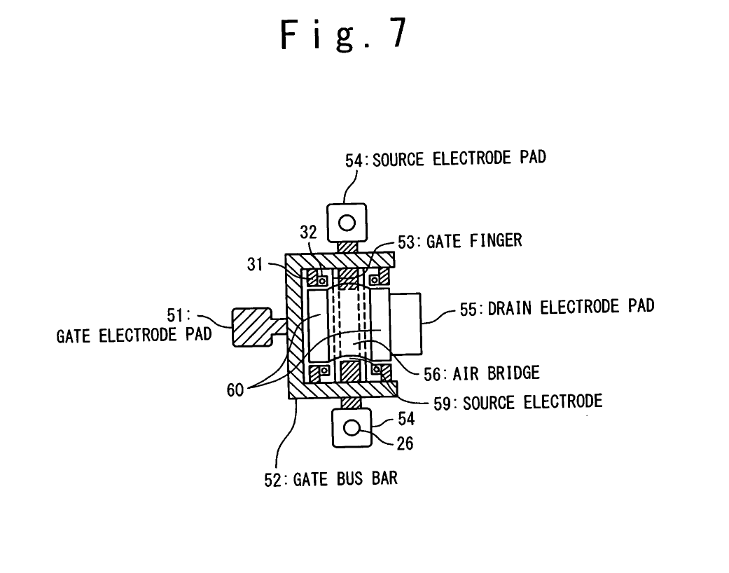

FIG. 7 is a schematic view for describing about an overall configuration of a semiconductor device of a third exemplary embodiment of the present invention. This semiconductor device is identical to the multi-finger FET of the second exemplary embodiment to which a ladder circuit is added.

The multi-finger FET of FIG. 7 includes a gate electrode pad 51, a gate bus bar 52, two gate fingers 53, two source electrode pads 54, a source electrode 59, a drain electrode pad 55, two drain electrode 60, an air bridge 56, a resistor 31 and a capacitor 32 with a via hole. The gate electrode pad 51, the gate bus bar 52, two gate fingers 53, two source electrode pads 54, the source electrode 59, the drain electrode pad 55, two drain electrodes 60 and the air bridge 56 corresponds respectively to each components of FIG. 5. The resistor 31 and the capacitor 32 with a via hole correspond to the ladder circuit of the present exemplary embodiment. The capacitor 32 with a via hole is grounded via the via hole.

This ladder circuit is configured by connecting the resistor 31 and the capacitor 32 with a via hole in series. This ladder circuit is connected with the gate finger 53 in series to suppress or avoid a loop oscillation.

Here, if the values of the resistor 31 and the capacitor 32 with a via hole are shown by R and C, respectively, a resonant frequency f of the ladder circuit as a parallel resonance circuit is given as below.

f=½πRC

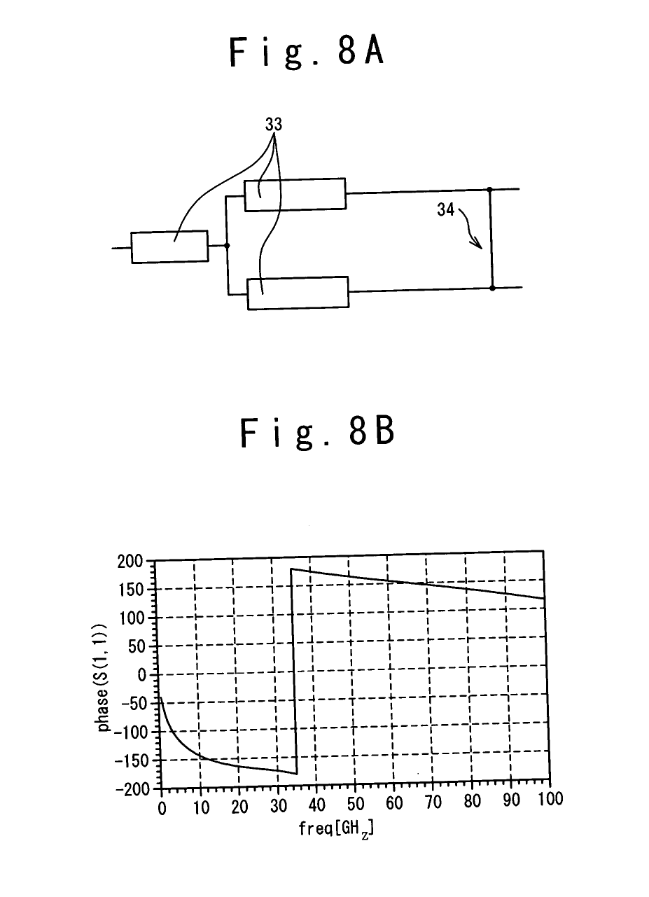

FIG. 8A is a circuit diagram for describing about a closed circuit obtained by excluding a ladder circuit from the semiconductor device of the present exemplary embodiment. This closed circuit includes three gate bus bars 33 and a gate finger 34. Here, three gate bus bars 33 in FIG. 8A correspond to the two end sections of the gate bus bar 52 and the gate electrode pad 51 in FIG. 7. The gate finger 34 in FIG. 8A corresponds to the gate finger 53 in FIG. 7.

FIG. 8B is a graph for describing about a calculating result of a phase difference of a closed circuit obtained by excluding a ladder circuit from the semiconductor device of the present exemplary embodiment. In this graph, the horizontal axis and the vertical axis show a frequency and a phase difference, respectively.

A loop oscillation is likely to occur when the phase difference is near 180 degrees. This phase difference is determined by a combination of the lengths of the gate bus bar and the gate finger on a layout.

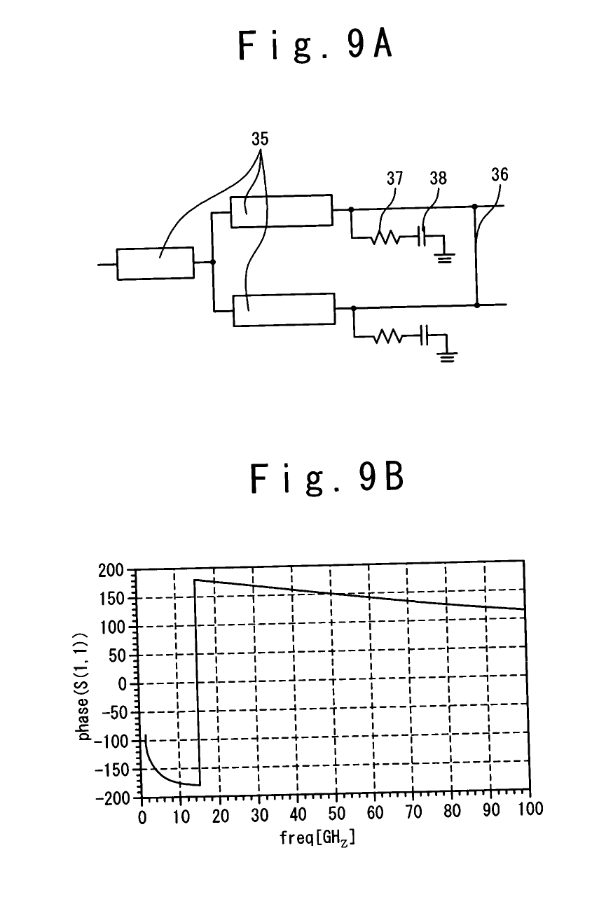

FIG. 9A is a circuit diagram for describing about the semiconductor of the present exemplary embodiment, that is, a closed circuit in which a ladder circuit is provided. This closed circuit includes three gate bus bar 35, a gate finger 36 and two ladder circuits. Each of two ladder circuits includes a resistor 37 and a grounded capacitor 38. The gate bus bar 35 in FIG. 9A corresponds to two end sections of the gate bus bar 52 and the gate electrode pad 51 in FIG. 7. The gate finger 36 in FIG. 9A corresponds to the gate finger 53 in FIG. 7. The resistor 37 and the grounded capacitor 38 in FIG. 9A correspond to the resistor 31 and the capacitor 32 with a via hole in FIG. 7.

FIG. 9B is a graph for describing about a calculating result of a phase difference of the semiconductor of the present exemplary embodiment, that is, a closed circuit in which a ladder circuit is provided. In this graph, the horizontal axis shows a frequency and the vertical axis shows a phase difference, respectively.

A loop oscillation frequency bandwidth, which is determined by a combination of lengths of the gate bus bar and the gate finger on a layout, can be avoided by providing a parallel resonance circuit. Therefore, a loop oscillation condition can be avoided in a desired operation frequency bandwidth by using this resonant frequency. Thus, a stable operation becomes possible in a closed circuit network of a gate finger of which both a starting point and an end point are connected to the gate bus bar.

### EXAMPLE

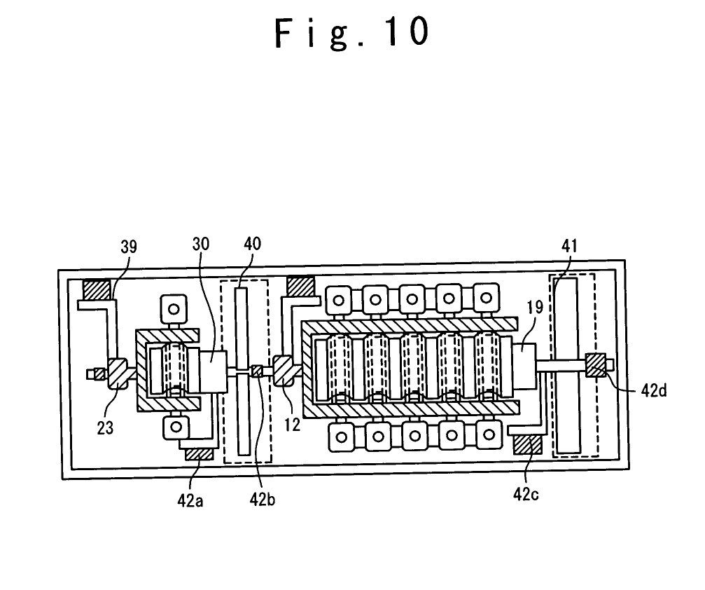

FIG. 10 is a schematic view for describing about a configuration in an example of an MMIC (Monolithic Microwave Integrated Circuit) based on the multi-finger configuration of the semiconductor device of the present invention. This MMIC includes a bias circuit 39, the multi-finger FET in the second exemplary embodiment of the present invention, an inter-stage signal circuit 40, the multi-finger FET in the first exemplary embodiment of the present invention, an output matching circuit 41 and a plurality of capacitor 42a-42d.

In this MMIC, the bias circuit 39 is connected to the gate electrode pad 23 in the multi-finger FET of the second exemplary embodiment of the present invention. The drain electrode pad 30 of the multi-finger FET of the second exemplary embodiment of the present embodiment is connected to a first capacitor 42a and the inter-stage signal circuit 40. The inter-stage signal circuit 40 is connected to the gate electrode pad 12 in the multi-finger FET of the first exemplary embodiment of the present invention via a second capacitor 42b. The drain electrode pad 19 of the multi-finger FET of the first exemplary embodiment of the present invention is connected to a third capacitor 42c. The drain electrode pad 19 of the multi-finger FET of the first exemplary embodiment of the present invention is connected to a fourth capacitor 42d and the output matching circuit 41.

In this example, a high gain characteristic can be reached in a frequency bandwidth from the microwave band to the millimeter wave band.

In same time, an expansion to a high gain MMIC becomes possible.

The multi-finger configuration of the present invention can be expanded to a high gain FET and MMIC using a compound semiconductor used in a high frequency FET, like GaAs (Gallium Arsenide), InP (Indium Phosphide), GaN (Gallium Nitride), SiC (Silicon Carbide) and ZnO (Zinc Oxide), and a Si (silicon) based semiconductor, like CMOS (Complementary Metal Oxide Semiconductor) and SiGe (Silicon Germanium).

The present invention has been described above by referring to exemplary embodiments (and example); however, the present invention is not supposed to be limited by above exemplary embodiments (and example). The configurations and the details of the present invention can be given various changes in a scope of the present invention that skilled person may understand.

This application claims a priority based on Japanese Laid-Open Application 2009-83063 filed on Mar. 30, 2009 of which all the disclosures are incorporated in this application.

1. A semiconductor device comprising:
a source electrode;
a drain electrode;
a gate electrode disposed between said source electrode and said drain electrode; and
a gate power feeding line connected to both ends of said gate electrode.

2. The semiconductor device according to claim 1, further comprising:
a first ground section configured to ground one end of said source electrode; and
a second ground section configured to ground another end of said source electrode.

3. The semiconductor device according to claim 1, further comprising:
a parallel resonance circuit configured to adjust a condition of a loop oscillation of said gate electrode and said gate power feeding line.

4. The semiconductor device according to claim 3,
wherein said parallel resonance circuit comprises:
a resistor of which one end is connected to said gate power feeding line; and
a capacitor of which one end is connected to another end of said resistor, and
wherein another end of said capacitor is grounded.

5. The semiconductor device according to claim 1, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

6. The semiconductor device according to claim 5 comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.

7. The semiconductor device according to claim 2, further comprising:
a parallel resonance circuit configured to adjust a condition of a loop oscillation of said gate electrode and said gate power feeding line.

8. The semiconductor device according to claim 7,
wherein said parallel resonance circuit comprises:
a resistor of which one end is connected to said gate power feeding line; and
a capacitor of which one end is connected to another end of said resistor, and
wherein another end of said capacitor is grounded.

9. The semiconductor device according to claim 2, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

10. The semiconductor device according to claim 3, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

11. The semiconductor device according to claim 7, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

12. The semiconductor device according to claim 4, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

13. The semiconductor device according to claim 8, further comprising:
another drain electrode disposed on another side of said source electrode from said drain electrode;
another gate electrode disposed between said source electrode and said another drain electrode; and
an air bridge configured to cross said gate electrode, said source electrode and said another gate electrode and connect said drain electrode with said another drain electrode.

14. The semiconductor device according to claim 9, comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.

15. The semiconductor device according to claim 10, comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.

16. The semiconductor device according to claim 12, comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.

17. The semiconductor device according to claim 12, comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.

18. The semiconductor device according to claim 13, comprising:
a plurality of source electrodes;
a plurality of drain electrode;
a plurality of gate electrode; and
a plurality of air bridges,
wherein said plurality of source electrodes and said plurality of drain electrodes are alternatively disposed, one by one,
wherein each of said plurality of gate electrodes is disposed one by one between a source electrode and a drain electrode, among said plurality of source electrodes and said plurality of drain electrodes, which are next to each other, and
wherein each of said plurality of air bridges crosses one source electrode and two gate electrodes disposed between two drain electrodes which are next to each other to connect said two drain electrodes which are next to each other.
